(19) United States
(12) Patent Application Publication
(10) Pub. No.: US 2016/0314850 A1
(43) Pub. Date: Oct. 27, 2016

(54) SHIFT REGISTER UNIT, METHOD FOR DRIVING THE SAME, GATE DRIVER CIRCUIT AND DISPLAY DEVICE

(71) Applicants: BOE TECHNOLOGY GROUP CO., LTD., Beijing (CN); HEFEI BOE OPTOELECTRONICS TECHNOLOGY CO., LTD., Anhui (CN)

(72) Inventors: Honggang GU, Beijing (CN); Xiaohe LI, Beijing (CN); Xianjie SHAO, Beijing (CN); Bo LIU, Beijing (CN); Lili YAO, Beijing (CN)

(73) Assignees: BOE TECHNOLOGY GROUP CO., LTD., Beijing (CN); HEFEI BOE OPTOELECTRONICS TECHNOLOGY CO., LTD., Anhui (CN)

(21) Appl. No.: 15/138,118

(22) Filed: Apr. 25, 2016

(30) Foreign Application Priority Data
Apr. 23, 2015 (CN) 201510198345.7

(51) Int. Cl. G11C 19/28; G06F 1/04; G09G 3/36

(52) U.S. Cl. CPC G11C 19/28; G09G 3/3677; G06F 1/04; G09G 3/3648; G09G 2310/08; G09G 2310/0286; G09G 2300/0861

(57) ABSTRACT

The present disclosure provides a shift register unit, its driving method, a gate driver circuit and a display device. The shift register unit includes an input end, a gate driving signal output end, a reset end, a pull-up transistor, a pull-down transistor, a pull-down node control module and a pull-up node control module. The pull-down node control module is configured to turn on the pull-down transistor at a first noise reduction stage so as to enable the gate driving signal output end to output a low level, and pull down the pull-down node to be at a low level at a second noise reduction stage. The pull-up node control module is configured to pull down the pull-up node to be at a low level at the first noise reduction stage and the second noise reduction stage, so as to turn off the pull-up transistor.

### CROSS-REFERENCE TO RELATED APPLICATION

The present application claims a priority of the Chinese patent application No. 201510198345.7 filed on Apr. 23, 2015, which is incorporated herein by reference in its entirety.

### TECHNICAL FIELD

The present disclosure relates to the field of display technology, in particular to a shift register unit, a method for driving the same, a gate driver circuit and a display device.

### BACKGROUND

Along with the development of the display technology, such a liquid crystal display panel with a high resolution and a narrow bezel has attracted more and more attention. One of the important methods for providing the display panel with the narrow bezel and high resolution is to use a gate shift register.

A driver for a thin film transistor-liquid crystal display (TFT-LCD) mainly includes a gate driver circuit and a data driver circuit. The gate driver circuit mainly consists of multiple levels of shift register units, and each stage of of the shift register unit is connected to a gate line. Pixel TFTs are scanned and driven progressively through output signals from the shift register units. However, for the conventional shift register unit, a coupling voltage may occur due to a clock signal, so it is impossible to minimize the noise interference while scanning the pixel TFTs bidirectionally. In addition, a large number of TFfs are adopted, an it is adverse to provide the display panel with a narrow bezel, to reduce the production cost and improve the yield thereof.

### SUMMARY

A main object of the present disclosure is to provide a shift register unit, its driving method, a gate driver circuit and a display device, so as to minimize the noise interference while achieving threshold voltage compensation and bidirectional scanning, reduce the amount of the TFTs and provide a narrow bezel.

In one aspect, he present disclosure provides in some embodiments a shift register unit, including an input end, a gate driving signal output end, and a reset end. The shift register unit further includes: a pull-up transistor, a gate electrode of which is connected to a pull-up node, a first electrode of which is configured to receive a first clock signal, and a second electrode of which is connected to the gate driving signal output end; a pull-down transistor, a gate electrode of which is connected to a pull-down node, a first electrode of which is connected to the gate driving signal output end, and a second electrode of which is configured to receive a first low level; a pull-down node control module connected to the pull-up node and the pull-down node, and configured to receive the first low level and a second clock signal, control the pull-down node to be at a low level at a pre-charging stage within each display period, maintain the pull-down node at a low level at an outputting stage within each display period, pull up the pull-down node to be at a high level at a first noise reduction stage within each display period so as to t n the pull-down transistor and enable the gate driving signal output end to output a low level, and pull down the pull-down node to be at a low level at a second noise reduction stage within each display period; and a pull-up node control module connected to the pull-up node, the pull-down node, the input end and the reset end, and configured to receive a high level, the first low level and a second low level, pull up the pull-up node to be at a high level at the pre-charging stage within each display period and further pull up the pull-up node in a bootstrapping manner at the output stage within each display period so as to maintain the pull-up transistor in an on state and enable the gate driving signal output end to output the first clock signal, pull down the pull-up node to be at a low level at the first noise reduction stage within each display period, and maintain the pull-up node at the low level at the second noise reduction stage within each display period so as to turn off the pull-up transistor. The first clock signal is of a phase reverse to the second clock signal.

Alternatively, the shift register unit further includes an output noise reduction transistor, a gate electrode of which is configured to receive the second clock signal, a first electrode of which is connected to the gate driving signal output end and a second electrode of which is configured to receive the first low level. The output noise reduction transistor is turned on at the pre-charging stage and the first noise reduction stage within each display period, so as to perform noise reduction on the gate driving signal output end, thereby to enable the gate driving signal output end. to output a low level.

Alternatively, the pull-down node control module is further configured to receive the first clock signal, and pull up the pull-down node to be at a high level at the second noise reduction stage within each display period, so as to control the pull-up node to be at a low level through the pull-up node control module and enable the gate driving signal output end to output a low level.

Alternatively, the pull-down node control module includes: a first pull-down node control transistor, a gate electrode of which is connected to the pull-up node, a first electrode of which is connected to the pull-down node, and a second electrode of which is configured to receive the first low level; and a pull-down node control capacitor connected between the pull-down node and a second clock signal output end.

Alternatively, the pull-down node control module further includes a second pull-down node control transistor, a gate electrode of which is configured to receive the first clock signal, a first electrode of which is connected to the pull-down node, and a second electrode of which is configured to receive the first clock signal.

Alternatively, the pull-up node control module includes a first transistor, a second transistor, a pull-up node control transistor and a storage capacitor. A gate electrode of the pull-up node control transistor is connected to the pull-down node, a first electrode thereof is configured to receive he first low level, and a second electrode thereof is connected to the pull-up node. The storage capacitor is connected between the pull-up node and the gate driving signal output end. During forward scanning, a gate electrode of the first transistor is connected to the input end, a first electrode of the first transistor is configured to receive the high level, a second electrode of the first transistor is connected to the pull-up node, a gate electrode of the second transistor is connected to the reset end, a first electrode of the second transistor is connected to the pull-up node, and a second electrode of the second transistor is configured to receive the second low level. During backward scanning, the gate electrode of the first transistor is connected to the reset end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

In another aspect, the present disclosure provides in some embodiments a method for driving the above-mentioned shift register unit, including, within each display period, steps of: at a pre-charging stage, enabling an input end to receive a high level, enabling a reset end to receive a low level, enabling a first clock signal to be a low level, enabling a second clock signal to be a high level, pulling up a pull-up node to be at a high level under the control of a pull-up node control module so as to turn on a pull-up transistor, and pulling down a pull-down node to be at a low level under the control of a pull-down node control module, so as to turn off a pull-down transistor, turn on an output noise reduction transistor and enable a gate driving signal output end to output a low level; at an output stage, enabling the input end to receive a low level, enabling he reset end to receive a low level, enabling the first clock signal to be a high level, enabling the second clock signal to be a low level, pulling up the pull-up node in a bootstrapping manner under the control of the pull-up node control module so as to maintain the pull-up transistor in an on state and enable the gate driving signal output end to output the first clock signal, and maintaining the pull-down node at a low level under the control of the pull-down node control module; at a first noise reduction stage, enabling the input end to receive a low level, enabling the reset end to receive a high level, enabling the first clock signal to be a low level, enabling the second clock signal to be a high level, pulling down the pull-up node to be at a low level under the control of the pull-up node control module, and pulling up the pull-down node to be at a high level under the control of the pull-down node control module, so as to turn on the pull-down transistor to enable the gate driving signal output end to output a low level, and turn on the output noise reduction transistor to perform noise reduction on the gate driving signal output end and enable the gate driving signal output end to output a low level; and at a second noise reduction stage, enabling the input end to receive a low level, enabling the resetting end to receive a low level, enabling the first clock signal to be a high level, enabling the second clock signal to be a low level, maintaining the pull-up node at a low level under the control of the pull-up node control module to turn off the pull-up transistor, and pulling down the pull-down node to be at a low level under the control of the pull-down node control module.

Alternatively, at a stage subsequent to the second noise reduction stage within one display period and prior to a next display period, the method further includes repeating the steps at the first noise reduction stage and the second noise reduction stage.

Alternatively, the method further includes: at the second noise reduction stage within each display period, pulling up the pull-down node to be at a high level under the control of the pull-down node control module, so as to pull down the pull-up node to be at a low level under the control of the pull-up node control module and enable the gate driving signal output end to output a low level under the control of the output noise reduction transistor.

In yet another aspect, the present disclosure provides in some embodiments a gate driver circuit including a plurality of levels of the shift register units and arranged on an array substrate, wherein an input end of a first stage of shift register unit is configured to receive a start signal; apart from the first stage of shift register unit, an input end of each stage of shift register unit is connected to a gate driving signal output end of a previous stage of shift register unit; apart from a last stage of shift register unit, a reset end of each stage of shift register unit is connected to a gate driving signal output end of a next stage of shift register unit; and a reset end of the last stage shift register unit is configured to receive a reset signal.

In still yet another aspect, the present disclosure provides in some embodiments a display device including the above-mentioned gate driver circuit.

According to the shift register unit, the method for driving the same, the gate driver circuit and the display device in the embodiments of the present disclosure, when the gate driving signal output end is ineffective, the elements are used to perform the noise reduction continuously, so as to minimize the noise interference, thereby to prevent the occurrence of coupling voltage due to the clock signal and improve the yield. In addition, fewer TFTs are adopted as compared with the related art, so it is able to provide a narrow bezel, reduce the production cost and achieve bidirectional scanning.

### BRIEF DESCRIPTION OF THE DRAWINGS

FIG. 1 is a schematic view showing a shift register unit according to one embodiment of the present disclosure;

FIG. 2 is another schematic view showing the shift register unit according to one embodiment of the present disclosure;

FIG. 3 is yet another schematic view showing the shift register unit according to one embodiment of the present disclosure;

FIG. 4 is a schematic view showing a gate driver circuit according to one embodiment of the present disclosure;

FIG. 5 is a circuit diagram of an n^{th}-stage of shift register unit G(n) for forward scanning according to one embodiment of the present disclosure;

FIG. 6 is a sequence diagram of the shift register unit in FIG. 5 during the forward scanning;

FIG. 7 is another circuit diagram of the n^{th}-stage of shift register unit G(n) for forward scanning according to one embodiment of the present disclosure;

FIG. 8 is a sequence diagram of the shift register unit in FIG. 7 during the forward scanning;

FIG. 9 is yet another circuit diagram of the n^{th}-stage of shift register unit G(n) for forward scanning according to one embodiment of the present disclosure;

FIG. 10 is a circuit diagram of the n^{th}-stage of shift register unit G(n) for backward scanning according to one embodiment of the present disclosure;

FIG. 11 is another circuit diagram of the n^{th}-stage of shift register unit G(n) for backward scanning according to one embodiment of the present disclosure; and

FIG. 12 is yet another circuit diagram of the n^{th}-stage of shift register unit G(n) for backward scanning according to one embodiment of the present disclosure.

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

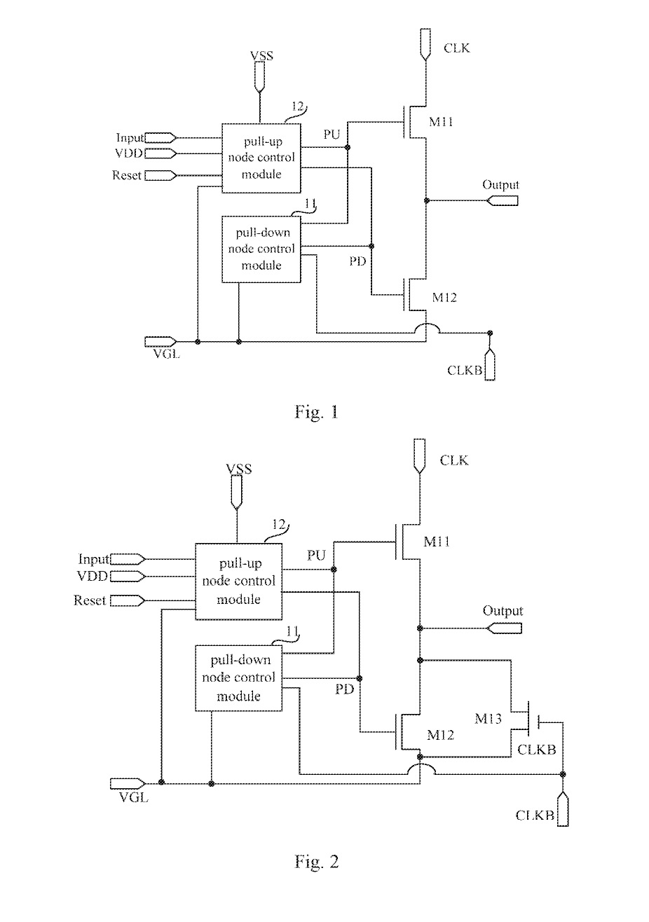

As shown in FIG. 1, the present disclosure provides in some embodiments a shift register unit, which includes an input end Input, a gate driving signal output end Output and a reset end Reset. The shift register unit further includes: a pull-up transistor M11, a gate electrode of which is connected to a pull-up node PU, a first electrode of which is configured to receive a first clock signal CLK, and a second electrode of which is connected to the gate driving signal output end Output; a pull-down transistor M12, a gate electrode of which is connected to a pull-down node PD, a first electrode of which is connected to the gate driving signal output end Output, and a second electrode of which is configured to receive a first low level VGL; a pull-down node control module 11 connected to the pull-up node PU and the pull-down node PD, and configured to receive the first low level VGL and a second clock signal CLKB, control the pull-down node PD to be at a low level at a pre-charging stage within each display period, maintain the pull-down node PD at a low level at an outputting stage within each display period, pull up the pull-down node PD to be at a high level at a first noise reduction stage within each display period so as to turn on the pull-down transistor M12 and enable the gate driving signal output end Output to output a low level, and pull down the pull-down node PD to be at a low level at a second noise reduction stage within each display period; and a pull-up node control module 12 connected to the pull-up node PU, the pull-down node PD, the input end Input and the reset end Reset, and configured to receive a high level VDD, the first low level VGL and a second low level VSS, pull up the pull-up node PU to be at a high level at the pre-charging stage within each display period and further pull up the pull-up node PU in a bootstrapping manner at the output stage within each display period so as to maintain the pull-up transistor M11 in an on state and enable the gate driving signal output end Output to output the first clock signal CLK, pull down the pull-up node PU to be at a low level at the first noise reduction stage within each display period, and maintain the pull-up node PU at the low level at the second noise reduction stage within each display period no as to turn off the pull-up transistor M11.

In the embodiments of the present disclosure, the pull-up transistor M11 and the pull-down transistor M12 are both n-type transistors, and the first clock signal CLK is of a phase reverse to the second clock signal CLKB.

According to the shift register unit in the embodiments of the present disclosure, it is able to perform the noise reduction continuously when the gate driving signal output end is disenable, so as to minimize the noise interference, thereby to prevent the occurrence of a coupling voltage due to the clock signal and improve the yield

The transistors adopted in all the embodiments of the present disclosure may be TFTs, field effect transistors (FETs) or any other elements having similar characteristics. In order to differentiate the two electrodes other than a gate electrode, the first electrode may be a source electrode or a drain electrode, while the second electrode may be a drain electrode or a source electrode. In addition, depending on the characteristics, the TFTs may include n-type transistors and p-type transistors. For a driver circuit in the embodiments of the present disclosure, all the transistors are n-type transistors. Of course, the p-type transistors may also be used, which also fall within the scope of the present disclosure.

To be specific, as shown in FIG. 2, the shift register unit further includes an output noise reduction transistor M13, a gate electrode of which is configured to receive the second clock signal CLKB, a first electrode of which is connected to the gate driving signal output end Output and a second electrode of which is configured to receive the first low level VGL. The output noise reduction transistor is turned on at the pre-charging stage and the first noise reduction stage within each display period, so as to perform noise reduction on the gate driving signal output end Output, thereby to enable the gate driving signal output end Output to output a low level.

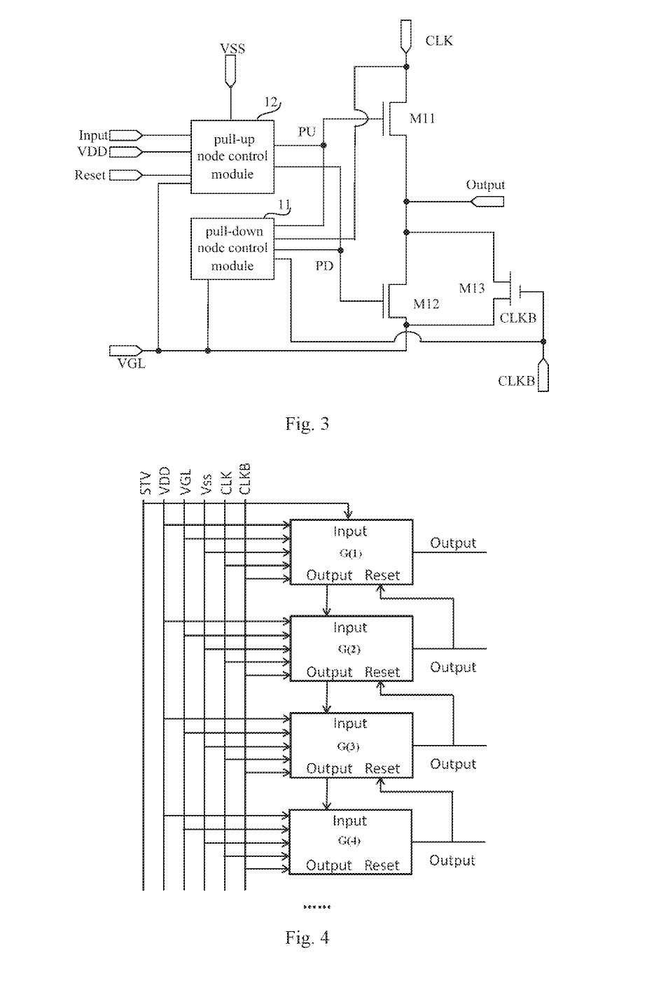

During the implementation, as shown in FIG. 3, the pull-down node control module 11 is further configured to receive the first clock signal CLK, and pull up the pull-down node PD to be at a high level at the second noise reduction stage with each display period, so as to control the pull-up node PU to be at a low level through the pull-up node control module 12 and enable the gate driving signal output end Output to output a low level.

In FIG. 3, the pull-down node control module 11 and the pull-up node control module 12 controls the gate driving signal output end Output to output a low level at the second noise reduction stage within each display period through the output noise reduction transistor M13, so as to further reduce the noise.

To be specific, the pull-down node control module includes: a first pull-down node control transistor, a gate electrode of which is connected to the pull-up node, a first electrode of which is connected to the pull-down node, and a second electrode of which is configured to receive the first low level; and a pull-down node control capacitor connected between the pull-down node and a second clock signal output end.

To be specific, the pull-down node control module further includes a second pull-down node control transistor, a gate electrode of which is configured to receive the first clock signal, a first electrode of which is connected to the pull-down node, and a second electrode of which is configured to receive the first clock signal.

To be specific, the pull-up node control module includes a first transistor, a second transistor, a pull-up node control transistor and a storage capacitor. A gate electrode of the pull-up node control transistor is connected to the pull-down node, a first electrode thereof is configured to receive the first low level, and a second electrode thereof is connected to the pull-up node. The storage capacitor is connected between the pull-up node and the gate driving signal output end. During forward scanning, a gate electrode of the first transistor is connected to the input end, a first electrode of the first transistor is configured to receive the high level, a second electrode of the first transistor is connected to the pull-up node, a gate electrode of the second transistor is connected to the reset end, a first electrode of the second transistor is connected to the pull-up node, and a second electrode of the second transistor is configured to receive the second low level. During backward scanning, the gate electrode of the first transistor is connected to the reset end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

As shown in FIG. 4, the present disclosure further provides in some embodiments a gate driver circuit, which includes multiple stages of the above-mentioned shift register units arranged on an array substrate. An input end of a first-stage of shift register unit G(1) is configured to receive a start signal STV Apart from the first-stage of shift register unit, an input end Input of each stage of shift register unit is connected to a gate driving signal output end Output of a previous-stage of shift register unit, and apart from a last-stage of shift register unit, a reset end Reset of each stage shift register unit is connected to a gate driving signal output end Output of a next-stage of shift register unit. A reset end of the last-stage shift register unit is configured to receive a reset signal (not shown).

In FIG. 4, G(2) represents a second-stage of shift register unit, G(3) represents a third-stage of shift register unit, and G(4) represents a fourth-stage of shift register unit.

The shift register unit will be described hereinafter in conjunction with the embodiments.

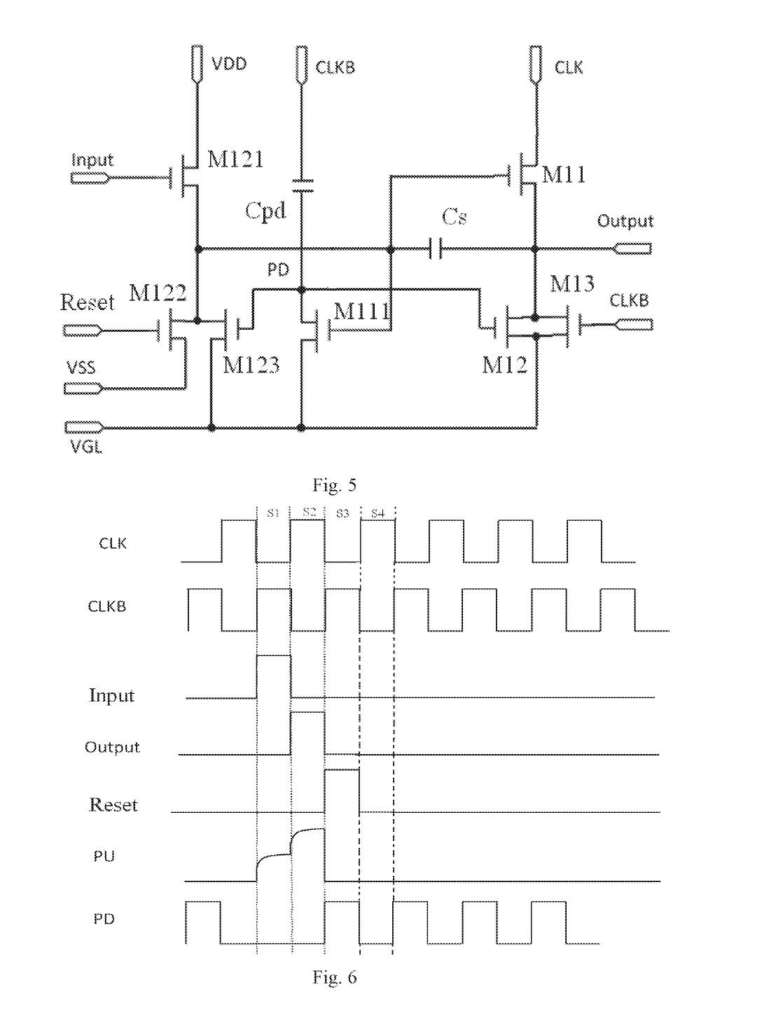

As shown in FIG. 5, in a first embodiment of the present disclosure, an n^{th}-stage of shift register unit G(n) for forward scanning (n is a positive integer) includes an input end Input, a gate driving signal output end Output, a reset end Reset, a pull-up transistor M11, a pull-down transistor M12, a pull-down node control module 11, a pull-up node control module 12 and an output noise reduction transistor M13. A gate electrode of the pull-up transistor M11 is connected to a pull-up node PU, a first electrode of the pull-up transistor M11 is configured to receive a first clock signal CLK, and a second electrode of the pull-up transistor M11 is connected to the gate driving signal output end Output. A gate electrode of the pull-down transistor M12 is connected to a pull-down node PD, a first electrode of the pull-down transistor M12 is connected to the gate driving signal output end Output, and a second electrode of the pull-down transistor M12 is configured to receive a first low level VGL.

The pull-down node control module 11 includes: a first pull-down node control transistor M111, a gate electrode of which is connected to the pull-up node PU, a first electrode of which is connected to the pull-down node PD, and a second electrode of which is configured to receive the first low level VGL; and a pull-down node control capacitor Cpd connected between the pull-down node PD and a second clock signal output end for outputting the second clock signal CLKB.

The pull-up node control module 12 includes a first transistor M121, a second transistor M122, a pull-up node control transistor M123 and a storage capacitor Cs. A gate electrode of the pull-up node control transistor M123 is connected to the pull-down node PD, a first electrode thereof is configured to receive the first low level VGL, and a second electrode thereof is connected to the pull-up node PU. The storage capacitor Cs is connected between the pull-up node PU and the gate driving signal output end Output. A gate electrode of the first transistor M121 is connected to the input end input, a first electrode thereof is configured to receive the high level VDD, and a second electrode thereof is connected to the pull-up node PU A gate electrode of the second transistor M122 is connected to the reset end Reset, a first electrode thereof is connected to the pull-up node PU, and a second electrode thereof is configured to receive the second low level VSS.

A gate electrode of the output noise reduction transistor M13 is configured to receive the second clock signal CLKB, a first electrode thereof is connected to the gate driving signal output end Output and a second electrode thereof is configured to receive the first low level VGL. The output noise reduction transistor M13 is turned on at the pre-charging stage and the first noise reduction stage within each display period, no as to perform noise reduction on the gate driving signal output end Output, thereby to enable the gate driving signal output end Output to output a low level.

FIG. 6 shows an operating process for the shift register unit in FIG. 5 within a display period during the forward scanning.

At a pre-charging stage S1, Input receives a high level (i.e., Input is connected to Output of the previous-stage of shift register unit) so as to on M121. CLK is a low level, and Cs is charged by VDD through M121, so as to pull up PU to be at a high level, thereby to turn on M111 and pull down PD to be at a low level. At this time. M12 and M123 are both turned off, and CLKB is a high level, so as to perform noise reduction on Output, thereby to stably output a gate driving signal.

At an output stage S2, Input receives a low level, M121 is turned off, PU is maintained at a high level, and M11 is maintained in an on state. At this time, CLK is a high level, and PU is pulled up continuously due to a bootstrapping effect, so as to continuously maintain M11 in the on state and enable Output to output CLK. PU is at a high level, and M111 is still in the on state, so as to maintain M12 and M123 in an off state. CLKB is a low level, and M13 is turned off, so as to stably output the gate driving signal.

At a first noise reduction stage S3, Input receives a low level, Reset receives a high level (i.e., the gate driving signal for the next-stage of shift register unit), so as to turn on M122 and pull down PU to be at a low level, thereby to turn off M11. CLKB is also a high level, and M13 is in the off state, so as to enable Output to output a low level, thereby to perform noise reduction on Output. At this time, PU is at a low level, M111 is turned off, PD is pulled up to be at a high level by CLKB through Cpd, and M12 is turned on, so as to perform noise reduction on Output. Because PD is at a high level, M123 is turned on, so as to perform noise reduction on PU. In this way, it is able to eliminate a coupling noise voltage generated due to CLK, thereby to stably output the gate driving signal at a low level.

At a second noise reduction stage S4, CLKB is a low level, M13 is turned off, PD is pulled down to be at a low level by CLKB through Cpd, and M123 and M12 are both turned off. At this time, Reset is also at a low level, so M122 is turned off and PU is maintained at a low level.

Prior to a next frame, the first noise reduction stage S3 and the second noise reduction stage 4 may be repeated by the shift register unit all the time, so as to perform the noise reduction on the pull-up node PU and the gate driving signal output end Output at the first noise reduction stage S3.

When the backward scanning is to be performed by the shift register unit in FIG. 5, it is merely required to exchange VDD and VSS, and exchange Input and Reset, each other. The operating process for the backward scanning is identical to that for the forward scanning, and thus will not be particularly defined herein.

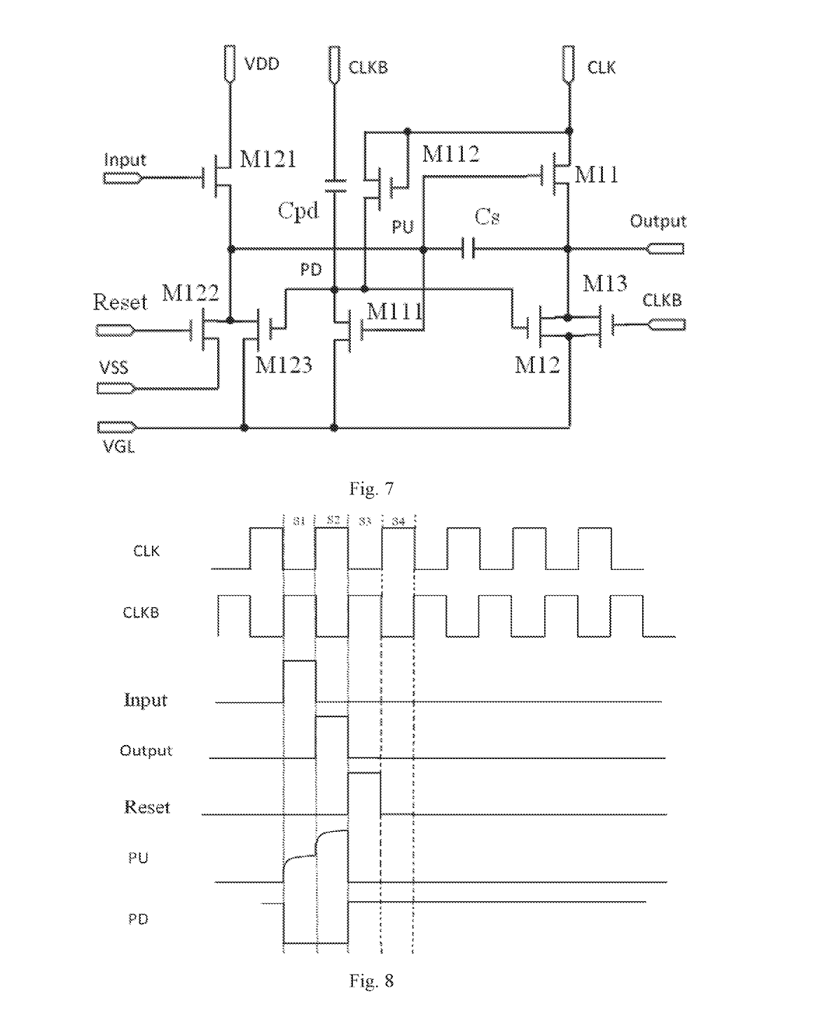

As shown in FIG. 7, in a second embodiment of the present disclosure, the n^{th}-stage) of shift register unit G(n) for forward scanning includes an additional second pull-down node control transistor M112 as compared with that in FIG. 5. A gate electrode of the second pull-down node control transistor M112 is configured to receive the first clock signal CLK, a first electrode thereof is connected to the pull-down node PD, and a second electrode thereof is configured to receive the first clock signal CLK.

FIG. 8 shows an operating process for the shift register unit in FIG. 7 within a display period during the forward scanning.

At the pre-charging stage S1, Input receives a high level (i.e., Input is connected to Output of the previous-stage of shift register unit), so as to turn on M121. CLK is a low level, and Cs is charged by VDD through M121, so as to pull up PU to be at a high level. At this time, M111 is turned on, so as to pull down PD to be at a low level, thereby to turn off M12 and M123. CLKB is a high level, and M13 is turned on, so as to perform noise reduction on Ouput, thereby to stably output the gate driving signal.

At the output stage S2, Input receives a low level, M121 is turned off, PU is continuously maintained at a high level, and M11 is maintained in the on state. At this time, CLK is a high level, and PU is continuously pulled up due to a bootstrapping effect, so as to continuously maintain M11 in the on state and enable Output to output CLK. PU is at a high level, M111 is still in the on state, CLKB is a low level and PD is maintained at a low level, so as to maintain M12 and M123 in the off state. CLKB is a low level, so as to maintain M13 in the off state, thereby to stably output the gate driving signal.

At the first noise reduction stage S3, Reset receives a high level (i.e., the gate driving signal for the next-stage of shift register unit), so as to enable M122 to be in the on state and pull down PU to be at a low level, thereby to turn off M11 and M111. CLKB is also a high level, and M13 is in the on state, so as to pull down the gate driving signal to VGL. In addition, CLKB is a high level, PD is pulled up to be at a high level by CLKB through Cpd, and M123 and M12 are both in the on state, so as to discharge PU and Output.

At the second noise reduction stage S4, CLK is a high level, and CLKB is a low level. At this time, PU is at a low level. M111 and M11 are both in the off state, and M112 is in the on state, so as to pull up PD to be at a high level and turn on M12, thereby to perform noise reduction on Output. Meanwhile, because PD is at a high level, M123 is turned on, so as to perform noise reduction on PU. In this way, it is able to eliminate a coupling noise voltage generated due to CLK, thereby to stably output the gate driving signal at a low level.

Prior to a next frame, the first noise reduction stage S3 and the second noise reduction stage 4 may be repeated by the shift register unit all the time, so as to perform the noise reduction on the pull-up node PU and the gate driving signal output end Output continuously.

In the second embodiment of the present disclosure as shown in FIG. 7, due to the additional M112, it is able to for the gate driving signal output end Output to output a low level under the control of the output noise reduction transistor M13 at the reset stage and the second noise reduction stage within each display period, thereby to further reduce the noise interference.

When the backward scanning is to be performed by the shift register unit in FIG. 7, it is merely required to exchange VDD and VSS, and exchange Input and Reset, with each other. The operating process for the backward scanning is identical to that for the forward scanning, and thus will not be particularly defined herein.

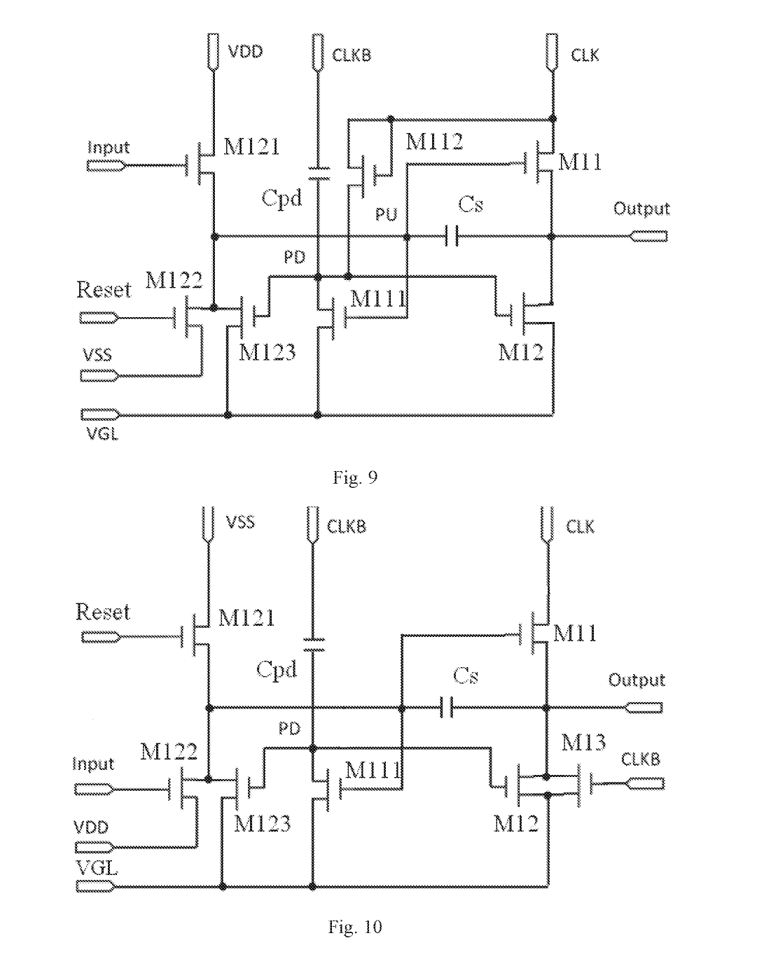

As shown in FIG. 9, in a third embodiment of the present disclosure, the n^{th}-stage of shift register unit G(n) for forward scanning (n is a positive integer) includes no output noise reduction transistor M13 as compared with that in FIG. 7.

FIG. 8 shows an operating process for the shift register unit in FIG. 9 within a display period during the forward scanning.

At the pre-charging stage S1, input receives a high level (i,e., Input is connected to Output of the previous-stage of shift register unit), so as to turn on M121. CLK is a low level, and Cs is charged by VDD through M121, so as to pull up PU to be at a high level. At this time, M111 is turned on, so as to pull down PD to be at a low level, thereby to turn off M12 and M123.

At the output stage S2, Input receives a low level, M121 is turned off. PU is continuously maintained at a high level, and M11 is maintained in the on state. At this time, CLK is a high level, and PU is pulled up continuously due to a bootstrapping effect, so as to continuously maintain M11 in the on state and enable Output to output CLK. PU s at a high level, M111 is still maintained in the on state, CLKB is a low level, and PD is maintained at a low level, so as to continuously maintain M12 and M123 in the off state.

At the first noise reduction stage S3, Reset receives a high level (i.e., the gate driving signal for the next-stage of shift register unit), so as to enable M122 to be in the on state and pull down PU to be at a low level, thereby to turn off M11 and M111. Because CLKB is a high level, PD is pulled up to be at a high level by CLKB through Cpd. At this time, M123 and M12 are b th in the on state, so as to discharge PU and Output.

At the second noise reduction stage S4, CLK is a high level and CLKB is a low level. At this time, PU is at a low level, M11 and M11 are both in the off state, M112 is turned on, so as to pull up PD to be at a high level and turn on M12, thereby to perform noise reduction on Output. Meanwhile, PD is at a high level, and M123 is turned on, so as to perform noise reduction on PU. In this way, it is able to eliminate a coupling noise voltage generated due to CLK, thereby to stably output the gate driving signal at a low level.

Prior to a next frame, the first noise reduction stage S3 and the second noise reduction stage 4 may be repeated by the shift register unit all the time, so as to perform the noise reduction on the pull-up node PU and the gate driving signal output end Output continuously.

As shown in FIG. 10, in a first embodiment of the present disclosure, an n^{th}-stage of shift register unit G(n) for backward scanning (n is a positive integer) includes an input end Input, a gate driving signal output end Output, a reset end Reset, a pull-up transistor M11, a pull-down transistor M12, pull-down node control module 11, a pull-up node control module 12 and an output noise reduction transistor M13. A gate electrode of the pull-up transistor M11 is connected to a pull-up node PU, a first electrode of the pull-up transistor M11 is configured to receive a first clock signal CLK, and a second electrode of the pull-up transistor M11 is connected to the gate driving signal output end Output. A gate electrode of the pull-down transistor M12 is connected to a pull-down node PD, a first electrode of the pull-down transistor M12 is connected to the gate driving signal output end Output, and a second electrode of the pull-down transistor M12 is configured to receive a first low level VGL.

The pull-down node control module 11 includes: a first pull-down node control transistor M111, a gate electrode of which is connected to the pull-up node PU, a first electrode of which is connected to the pull-down node PD, and a second electrode of which is configured to receive the first low level VGL; a pull-down node control capacitor Cpd connected between the pull-down node PD and a second clock signal output end for outputting the second clock signal CLKB.

The pull-up node control module 12 includes a first transistor M121, a second transistor M122, a pull-up node control transistor M123 and a storage capacitor Cs. A gate electrode of the pull-up node control transistor M123 is connected to the pull-down node PD, a first electrode thereof is configured to receive the first low level VGL, and a second electrode thereof is connected to the pull-up node PU. The storage capacitor Cs is connected between the pull-up node PU and the gate driving signal output end Output. A gate electrode of the first transistor M121 is connected to the reset end Reset, a first electrode thereof is configured to receive the second low level VSS, and a second electrode thereof is connected to the pull-up node PU. A gate electrode of the second transistor M122 is connected to the input end Input, a first electrode thereof is connected to the pull-up node PU, and a second electrode thereof is configured to receive the high level VDD.

A gate electrode of the output noise reduction transistor M13 is configured to receive the second clock signal CLKB, a first electrode thereof is connected to the gate driving signal output end Output and a second electrode thereof is configured to receive the first low level VGL. The output noise reduction transistor M13 is turned on at the pre-charging stage and the first noise reduction stage within each display period, so as to perform noise reduction on the gate driving signal output end Output, thereby to enable the gate driving signal output end Output to output a low level.

The first embodiment involving the n^{th}-stage of shift register unit G(n) for backward scanning corresponds to the second embodiment involving the n^{th}-stage of shift register unit G(n) for forward scanning, and FIG. 6 also shows the signal sequence for the n^{th}-stage of shift register unit G(n) in FIG. 10.

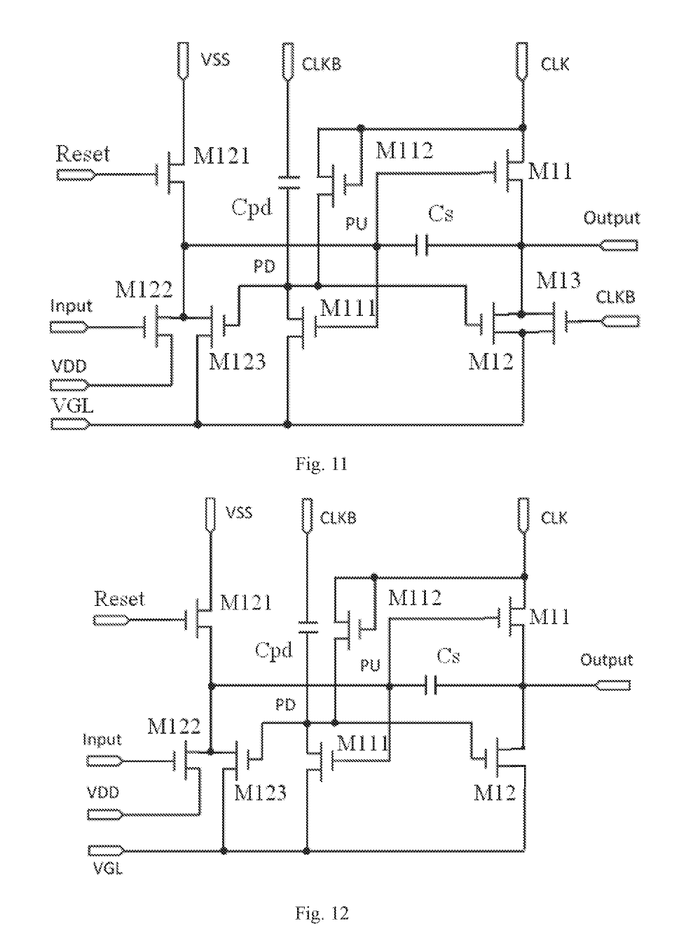

As shown in FIG. 11, in a second embodiment of the present disclosure, the n^{th}-stage of shift register unit G(n) for backward scanning (n is a positive integer) includes an additional second pull-down node control transistor M112 as compared) with the n^{th}-stage of shift register unit G(n) in FIG. 10. A gate electrode of the second pull-down node control transistor M112 is configured to receive the first clock signal CLK, a first electrode thereof is connected to the pull-down node PD, and a second electrode thereof is configured to receive the first clock signal CLK.

The second embodiment involving the n^{th}-stage of shift register unit G(n) for backward scanning corresponds to the second embodiment involving the n^{th}-stage of shift register unit G(n) for forward scanning, and FIG. 8 also shows the signal sequence for the n^{th}-stage of shift register unit G(n) in FIG. 11.

As shown in FIG. 12, in a third embodiment of the present disclosure, the n^{th}-stage of shift register unit G(n) for backward scanning (n is a positive integer) includes no output noise reduction transistor M13 as compared with that in FIG. 11.

The third embodiment involving the n^{th}-stage of shift register unit G(n) for backward scanning corresponds to the third embodiment involving the n^{th}-stage of shift register unit G(n) for forward scanning, and FIG. 8 also shows the signal sequence for the n^{th}-stage of shift register unit G(n) in FIG. 12.

As can be seen from the above, for a shift register including multiple levels of the above-mentioned shift register units, it is able to achieve the forward scanning and the backward scanning through an identical circuit, merely by changing a signal applied to the first electrode of the first transistor and a signal applied to the second electrode of the second transistor when switching a scanning mode. As a result, it is able to reduce the amount of the TFTs, thereby to reduce the power consumption.

The present disclosure further provides in some embodiments a gate driver circuit, which includes multiple levels of the above-mentioned shift register units. According to the gate driver circuit in the embodiments of the present disclosure, it is able to achieve a gate driving function, reduce the amount of signal lines and TFTs and provide a narrow bezel. In addition, it is also able to achieve the bidirectional scanning, improve the yield, reduce the production cost and improve the stability of the gate shift register. When the output end is disenable, it is able to perform the noise reduction continuously through all the elements, so as to minimize the noise interference, prevent the occurrence of a coupling voltage generated due to CLK and improve the yield. In addition, it is also able to prevent the occurrence of the output abnormality of the shift register unit due to threshold voltage drift of the TFT, thereby to prolong the service life thereof.

The present disclosure further provides in some embodiments a method for driving the above-mentioned shift register unit, which includes, within each display period, steps of: at a pre-charging stage, enabling an input end to receive a high level, enabling a reset end to receive a high level, enabling a first clock signal to be a low level, enabling a second clock signal to be a high level, pulling up a pull-up node to be at a high level under the control of a pull-up node control module so as to turn on a pull-up transistor, and pulling down a pull-down node to be at a low level under the control of a pull-down node control module, so as to turn off a pull-down transistor, turn on an output noise reduction transistor and enable a gate driving signal output end to output a low level; at an output stage, enabling the input end to receive a low level, enabling he reset end to receive a low level, enabling the first clock signal to be a high level, enabling the second clock signal to be a low level, pulling up the pull-up node in a bootstrapping manner under the control of the pull-up node control module so as to maintain the pull-up transistor in an on state and enable the gate driving signal output end to output the first clock signal, and maintaining the pull-down node at a low level under the control of the pull-down node control module; at a first noise reduction stage, enabling the input end to receive a low level, enabling the reset end to receive a high level, enabling the first clock signal to be a low level, enabling the second clock signal to be a high level, pulling down the pull-up node to be at a low level under the control of the pull-up node control module, and pulling up the pull-down node to be at a high level under the control of the pull-down node control module, so as to turn on the pull-down transistor to enable the gate driving signal output end to output a low level, and turn on the output noise reduction transistor to perform noise reduction on the gate driving signal output end and enable the gate driving signal output end to output a low level; and at a second noise reduction stage, enabling the input end to receive a low level, enabling the resetting end to receive a low level, enabling the first clock signal to be a high level, enabling the second clock signal to be a low level, maintaining the pull-up node at a low level under the control of the pull-up node control module to turn off the pull-up transistor, and pulling down the pull-down node to be at a low level under the control of the pull-down node control module.

To be specific, subsequent to the second noise reduction stage within one display period and prior to a next display period, the method further includes repeating the steps at the first noise reduction stage and the second noise reduction stage.

To be specific, the method further includes, at the second noise reduction stage within each display period, pulling up the pull-down node to be at a high level under the control of the pull-down node control module, so as to pull down the pull-up node to be at a low level under the control of the pull-up node control module and enable the gate driving signal output end to output a low level under the control of the output noise reduction transistor.

The present disclosure further provides in some embodiments a display device which includes the above-mentioned gate driver circuit. The display device may be a liquid crystal display, a liquid crystal television, an organic light-emitting diode (PLED) display panel, an OLED display, an OLED television or an electronic paper.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

What is claimed is:

1. A shift register unit, comprising an input end, a gate driving signal output end and a reset end, wherein the shift register unit further comprises:
a pull-up transistor, a gate electrode of which is connected to a pull-up node, a first electrode of which is configured to receive a first clock signal, and a second electrode of which is connected to the gate driving signal output end;
a pull-down transistor, a gate electrode of which is connected to a pull-down node, a first electrode of which is connected to the gate driving signal output end, and a second electrode of which is configured to receive a first low level;
a pull-down node control module connected to the pull-up node and the pull-down node, and configured to receive the first low level and a second clock signal, control the pull-down node to be at a low level at a pre-charging stage within each display period, maintain the pull-down node at a low level at an outputting stage within each display period, pull up the pull-down node to be at a high level at a first noise reduction stage within each display period so as to turn on the pull-down transistor and enable the gate driving signal output end to output a low level, and pull down the pull-down node to be at a low level at a second noise reduction stage within each display period; and
a pull-up node control module connected to the pull-up node, the pull-down node, the input end and the reset end, and configured to receive a high level, the first low level and a second low level, pull up the pull-up node to be at a high level at the pre-charging stage within each display period and further pull up the pull-up node in a bootstrapping manner at the output stage within each display period so as to maintain the pull-up transistor in an on state and enable the gate driving signal output end to output the first clock signal, pull down the pull-up node to be at a low level at the first noise reduction stage within each display period, and maintain the pull-up node at the low level at the second noise reduction stage within each display period so as to turn off the pull-up transistor, and
wherein the first clock signal is of a phase reverse to the second clock signal.

2. The shift register unit according to claim 1, further comprising an output noise reduction transistor, a gate electrode of which is configured to receive the second clock signal, a first electrode of which is connected to the gate driving signal output end and a second electrode of which is configured to receive the first low level, wherein the output noise reduction transistor is turned on at the pre-charging stage and the first noise reduction stage within each display period, so as to perform noise reduction on the gate driving signal output end, thereby to enable the gate driving signal output end to output a low level.

3. The shift register unit according to claim 1, wherein the pull-down node control module is further configured to receive the first clock signal, and pull up the pull-down node to be at a high level at the second noise reduction stage within each display period, so as to control the pull-up node to be at a low level through the pull-up node control module and enable the gate driving signal output end to output a low level.

4. The shift register unit according to claim 2, wherein the pull-down node control module is further configured to receive the first clock signal, and pull up the pull-down node to be at a high level at the second noise reduction stage within each display period, so as to control the pull-up node to be at a low level through the pull-up node control module and enable the gate driving signal output end to output a low level.

5. The shift register unit according to claim 3, wherein the node control module comprises:
a first pull-down node control transistor, a gate electrode of which is connected to the pull-up node, a first electrode of which is connected to the pull-down node, and a second electrode of which is configured to receive the first low level; and
a pull-down node control capacitor connected between the pull-down node and a second clock signal output end.

6. The shift register unit according to claim 5, wherein the pull-down node control module further comprises:
a second pull-down node control transistor, a gate electrode of which is configured to receive the first clock signal, a first electrode of which is connected to the pull-down node, and a second electrode of which is configured to receive the first clock signal.

7. The shift register unit according to claim 1, wherein the pull-up node control module comprises a first transistor, a second transistor, a pull-up node control transistor and a storage capacitor;
a gate electrode of the pull-up node control transistor is connected to the pull-down node, a first electrode thereof is configured to receive the first low level, and a second electrode thereof is connected to the pull-up node;
the storage capacitor is connected between the pull-up node and the gate driving signal output end;
during forward scanning, a gate electrode of the first transistor is connected to the input end, a first electrode of the first transistor is configured to receive the high level, a second electrode of the first transistor is connected to the pull-up node, a gate electrode of the second transistor is connected to the reset end, a first electrode of the second transistor is connected to the pull-up node, and a second electrode of the second transistor is configured to receive the second low level; and
during backward scanning, the gate electrode of the first transistor is connected to the reset end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

8. The shift register unit according to claim 2, wherein the pull-up node control module comprises a first transistor, a second transistor, a pull-up node control transistor and a storage capacitor;
a gate electrode of the pull-up node control transistor is connected to the pull-down node, a first electrode thereof is configured to receive the first low level, and a second electrode thereof is connected to the pull-up node;
the storage capacitor is connected between the pull-up node and the gate driving signal output end;
during forward scanning, a gate electrode of the first transistor is connected to the input end, a first electrode of the first transistor is configured to receive the high level, a second electrode of the first transistor is connected to the pull-up node, a gate electrode of the second transistor is connected to the reset end, a first electrode of the second transistor is connected to the pull-up node, and a second electrode of the second transistor is configured to receive the second low level; and
during backward scanning, the gate electrode of the first transistor is connected to the reset end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

9. A method for driving the shift register unit according to claim 1, comprising, within each display period, steps of:
at a pre-charging stage, enabling an input end to receive a high level, enabling a reset end to receive a low level, enabling a first clock signal to be a low level, enabling a second clock signal to be a high level, pulling up a pull-up node to be at a high level under the control of a pull-up node control module so as to turn on a pull-up transistor, and pulling down a pull-down node to be at a low level under the control of a pull-down node control module, so as to turn off a pull-down transistor, turn on an output noise reduction transistor and enable a gate driving signal output end to output a low level;
at an output stage, enabling the input end to receive a low level, enabling the reset end to receive a low level, enabling the first clock signal to be a high level, enabling the second clock signal to be a low level, pulling up the pull-up node in a bootstrapping manner under the control of the pull-up node control module so as to maintain the pull-up transistor in an on state and enable the gate driving signal output end to output the first clock signal, and maintaining the pull-down node at a low level under the control of the pull-down node control module;
at a first noise reduction stage, enabling the input end to receive a low level, enabling the reset end to receive a high level enabling the first clock signal to be a low level, enabling the second clock signal to be a high level, pulling down the pull-up node to be at a low level under the control of the pull-up node control module, and pulling up the pull-down node to be at a high level under the control of the pull-down node control module, so as to turn on the pull-down transistor to enable the gate driving signal output end to output a low level, and turn on the output noise reduction transistor to perform noise reduction on the gate driving signal output end and enable the gate driving signal output end to output a low level; and
at a second noise reduction stage, enabling the input end to receive a low level, enabling the resetting end to receive a low level, enabling the first clock signal to be a high level, enabling the second clock signal to be a low level, maintaining the pull-up node at a low level under the control of the pull-up node control module to turn off the pull-up transistor, and pulling down the pull-down node to be at a low level under the control of the pull-down node control module.

10. The method according to claim 9, further comprising, at a stage subsequent to the second noise reduction stage within one display period and prior to a next display period, repeating the steps at the first noise reduction stage and the second noise reduction stage.

11. The method according to claim 9, further comprising, at the second noise reduction stage within each display period, pulling up the pull-down node to be at a high level under the control of the pull-down node control module, so as to pull down the pull-up node to be at a low level under the control of the pull-up node control module and enable the gate driving signal output end to output a low level under the control of the output noise reduction transistor.

12. The method according to claim 10, further comprising, at the second noise reduction stage within each display period, pulling up the pull-down node to be at a high level under the control of the pull-down node control module, so as to pull down the pull-up node to be at a low level under the control of the pull-up node control module and enable the gate driving signal output end to output a low level under the control of the output noise reduction transistor.

13. A gate driver circuit, comprising a plurality of stages of the shift register units according to claim 1 and arranged on an array substrate.
wherein an input end of a first stage of shift register unit is configured to receive a start signal;
apart from the first stage of shift register unit, an input end of each stage of shift register unit is connected to a gate driving signal output end of a previous stage of shift register unit;
apart from a last stage of shift register unit, a reset end of each stage of shift register unit is connected to a gate driving signal output end of a next stage of shift register unit; and
a reset end of the last stage shift register unit is configured to receive a reset signal.

14. The gate driver circuit according to claim 13, wherein the shift register unit further comprises an output noise reduction transistor, a gate electrode of which is configured to receive the second clock signal, a first electrode of which is connected to the gate driving signal output end and a second electrode of which is configured to receive the first low level, wherein the output noise reduction transistor is turned on at the pre-charging stage and the first noise reduction stage within each display period, so as to perform noise reduction on the gate driving signal output end, thereby to enable the gate driving signal output end to output a low level.

15. The gate driver circuit according to claim 13, wherein the pull-down node control module is further configured to receive the first clock signal, and pull up the pull-down node to be at a high level at the second noise reduction stage within each display period, so as to control the pull-up node to be at a low level through he pull-up node control module and enable the gate driving signal output end to output a low level.

16. The gate driver circuit according to claim 14, wherein the pull-down node control module is further configured to receive the first clock signal, and pull up the pull-down node to be at a high level at the second noise reduction stage within each display period, so as to control the pull-up node to be at a low level through the pull-up node control module and enable the gate driving signal output end to output a low level.

17. The gate driver circuit according to claim 15, wherein the pull-down node control module comprises:
a first pull-down node control transistor, a gate electrode of which is connected to the pull-up node, a first electrode of which is connected to the pull-down node, and a second electrode of which is configured to receive the first low level; and
a pull-down node control capacitor connected between the pull-down node and a second clock signal output end.

18. The gate driver circuit according to claim 17, wherein the pull-down node control module further comprises:
a second pull-down node control transistor, a gate electrode of which is configured to receive the first clock signal, a first electrode of which is connected to the pull-down node, and a second electrode of which is configured to receive the first clock signal

19. The gate driver circuit according to claim 13, wherein the pull-up node control module comprises a first transistor, a second transistor, a pull-up node control transistor and a storage capacitor;
a gate electrode of the pull-up node control transistor is connected to the pull-down node, a first electrode thereof is configured to receive the first low level, and a second electrode thereof is connected to the pull-up node;
the storage capacitor is connected between the pull-up node and the gate driving signal output end;
during forward scanning, a gate electrode of the first transistor is connected to the input end, a first electrode of the first transistor is configured to receive the high level, a second electrode of the first transistor is connected to the pull-up node, a gate electrode of he second transistor is connected to the reset end, a first electrode of the second transistor is connected to the pull-up node, and a second electrode of the second transistor is configured to receive the second low level; and
during backward scanning, the gate electrode of the first transistor is connected to the reset end, the first electrode of the first transistor is configured to receive the second low level, the second electrode of the first transistor is connected to the pull-up node, the gate electrode of the second transistor is connected to the input end, the first electrode of the second transistor is connected to the pull-up node, and the second electrode of the second transistor is configured to receive the high level.

20. A display device, comprising the gate driver circuit according to claim 13.
